(19) United States
(12) Patent Application Publication
(10) Pub. No.: US 2020/0389998 A1
(43) Pub. Date: Dec. 10, 2020

(54) IMMERSION COOLING APPARATUS

(71) Applicants: Inventec (Pudong) Technology Corp., Shanghai (CN); Inventec Corporation, Taipei (TW)

(72) Inventors: Kai-Yang Tung, Taipei (TW); Hung-Ju Chen, Taipei (TW)

(21) Appl. No.: 16/572,526

(22) Filed: Sep. 16, 2019

(30) Foreign Application Priority Data
Jun. 6, 2019 (CN) 201910489644.4

(51) Int. Cl. H05K 7/20

(52) U.S. Cl. CPC H05K 7/203; F28D 15/04; H05K 7/20336

(57) ABSTRACT

An immersion cooling apparatus includes a chamber, a steam-discharging tube, a liquid-returning tube, and a heat-dissipating tube. The chamber has a steam-discharging outlet and a liquid-returning inlet for storing a cooling solution and containing a heat-generating member. The steam-discharging tube is communicated with the steam-discharging outlet to discharge steam generated by the cooling solution. The liquid-returning tube passes through the liquid-returning inlet to be immersed in the cooling solution. The heat-dissipating tube is communicated with the steam-discharging tube and the liquid-returning tube and is spaced apart from the chamber for cooling the steam into liquid and returning the liquid to the cooling solution through the liquid-returning tube.

### BACKGROUND OF THE INVENTION

### 1. Field of the Invention

The present invention relates to an immersion cooling apparatus, and more specifically, to an immersion cooling apparatus of immersing a liquid-returning tube into a cooling solution.

### 2. Description of the Prior Art

In general, an immersion cooling apparatus immerses heat-generating members (e.g. servers, hard disk drive arrays) into a cooling solution stored in a cooling chamber. In this cooling design, the cooling solution can absorb heat energy of the heat-generating member to generate steam, and then the steam can be cooled into liquid by a fan device. Finally, the cooled liquid can be transmitted back to the cooling chamber by a pump, so as to achieve the heat-dissipating purpose. In practical application, the immersion cooling apparatus needs to adopt a fanless cooling design for specific application (e.g. vehicle heat dissipation). In brief, the fanless cooling design involves guiding the steam to a heat-dissipating device via a heat-dissipating tube and then returning the cooled liquid back to the cooling chamber. However, since there is no channel for separating the steam from the liquid and the steam and the liquid have the opposite flowing directions in the heat-dissipating tube to cause a high flow resistance, the heat-dissipating effect and liquid-returning efficiency of the immersion cooling apparatus could be reduced considerably.

### SUMMARY OF THE INVENTION

The present invention provides an immersion cooling apparatus. The immersion cooling apparatus includes a chamber, a steam-discharging tube, a liquid-returning tube, and a heat-dissipating tube. The chamber has a steam-discharging outlet and a liquid-returning inlet for storing a cooling solution and containing a heat-generating member to make the heat-generating member immersed in the cooling solution. The steam-discharging tube has a first tube end and a second tube end. The first tube end is communicated with the steam-discharging outlet and located above the cooling solution to discharge steam generated by the cooling solution when the cooling solution absorbs heat energy of the heat-generating member to leave the chamber through the first tube end. The liquid-returning tube has a third tube end and a fourth tube end. The third tube end passes through the liquid-returning inlet to be immersed in the cooling solution. The heat-dissipating tube is communicated with the second tube end and the fourth tube end and spaced apart from the chamber for cooling the steam from the steam-discharging tube into liquid and returning the liquid to the cooling solution through the liquid-returning tube.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram of an immersion cooling apparatus according to an embodiment of the present invention.

FIG. 2 is a partial enlarged cross-sectional diagram of a liquid-returning tube in FIG. 1 being immersed in a cooling solution.

FIG. 3 is a cross-sectional diagram of an immersion cooling apparatus according to another embodiment of the present invention.

### DETAILED DESCRIPTION

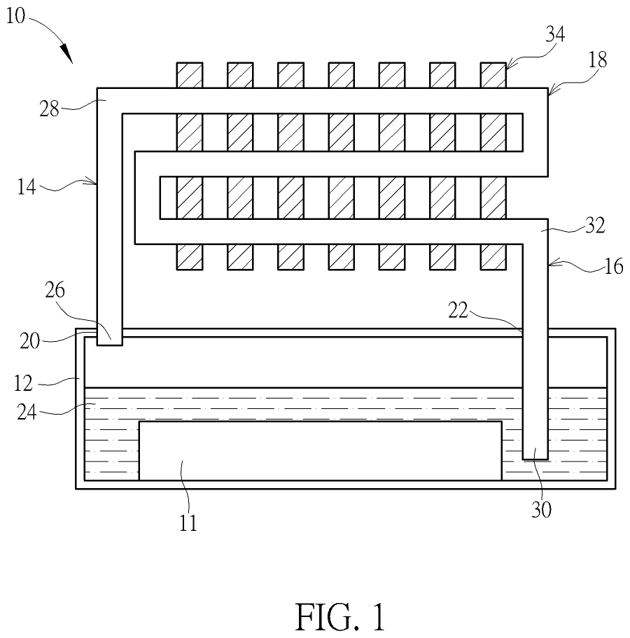

Please refer to FIG. 1, which is a cross-sectional diagram of an immersion cooling apparatus 10 according to an embodiment of the present invention. As shown in FIG. 1, the immersion cooling apparatus 10 includes a chamber 12, a steam-discharging tube 14, a liquid-returning tube 16, and a heat-dissipating tube 18. The chamber 12 could be a solution storage chamber commonly applied to an immersion cooling apparatus (the chamber design is commonly seen in the prior art and the related description is omitted herein) and has a steam-discharging outlet 20 and a liquid-returning inlet 22 for storing a cooling solution 24 and containing a heat-generating member (e.g. blade servers or hard disk drive arrays), so that the heat-generating member 11 can be immersed in the cooling solution 24. The cooling solution 24 could be an inert dielectric solution (e.g. mineral oil or silicone oil).

The steam-discharging tube 14 has a first tube end 26 and a second tube end 28. The first tube end 26 is communicated with the steam-discharging outlet 20 and located above the cooling solution 24 for discharging steam generated by the cooling solution 24 when the cooling solution 24 absorbs heat energy of the heat-generating member 11, such that the steam can leave the chamber 12 through the first tube end 26. The liquid-returning tube 16 has a third tube end 30 and a fourth tube end 32. The third tube end 30 passes through the liquid-returning inlet 22 to be immersed in the cooling solution 24. The heat-dissipating tube 18 is communicated with the second tube end 28 and the fourth tube end 32 and is spaced apart from the chamber 12.

Furthermore, the immersion cooling apparatus 10 could adopt a heat-dissipating design that the heat-dissipating tube 18 has a heat-dissipating device mounted thereon. For example, as shown in FIG. 1, the immersion cooling apparatus 10 could further include a heat-dissipating device 34. In this embodiment, the heat-dissipating device 34 could preferably be a heat-dissipating fin structure (but not limited thereto), and the heat-dissipating tube 18 is disposed through the heat-dissipating fin structure in a manner of bending back and forth, so as to make the heat-dissipating fin structure efficiently absorb the heat energy of the steam flowing into the heat-dissipating tube 18 to cool the steam into the liquid quickly. To be noted, via the design that the heat-dissipating tube 18 is spaced apart from the chamber 12, the immersion cooling apparatus 10 could further extend the heat-dissipating tube 18 having the heat-dissipating device 34 mounted thereon to a position where the temperature is lower (e.g. outdoor environment) or the airflow velocity is higher (e.g. the heat-dissipating tube 18 could extend outside a vehicle for heat dissipation via the airflow while the vehicle is moving), so as to greatly increase the heat-dissipating efficiency of the immersion cooling apparatus 10.

In such a manner, when the heat-generating member 11 is working to generate the heat energy, the steam generated by the cooling solution 24 when the cooling solution 24 absorbs the heat energy leaves the chamber 12 through the first tube end 26, and then flows into the heat-dissipating tube 18 through the steam-discharging tube 14. At this time, the heat-dissipating tube 18 can cool the steam from the steam-discharging tube 14 into the liquid via the heat-dissipating device 34 contacting the external environment outside the immersion cooling apparatus 10. Subsequently, the cooled liquid can flow through the liquid-returning tube 16 and then flow into the cooling solution 24 through the third tube end 30 immersed in the cooling solution 24.

During this process, via the design that the liquid-returning tube 16 is immersed in the cooling solution 24, the present invention can surely prevent the steam generated by the cooling solution 24 from leaving the chamber 12 through the third tube end 30 of the liquid-returning tube 16. As such, the present invention can limit the cooling solution 24 to flow in only one way from the steam-discharging tube 14 to the liquid-returning tube 16 through the heat-dissipating tube 18, so as to reduce the flowing resistance in the heat-dissipating tube 18. Thus, the prior art problem that the steam and the liquid have the opposite flowing directions in the heat-dissipating tube to cause the high flow resistance can be efficiently solved, so as to greatly improve the heat-dissipating effect and the liquid-returning efficiency of the immersion cooling apparatus.

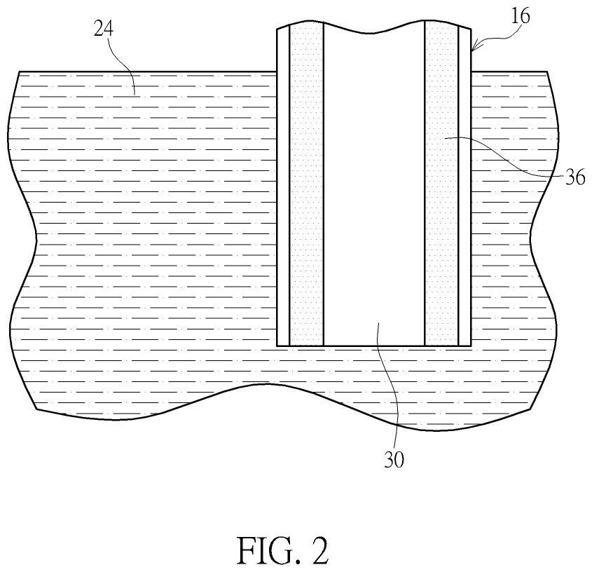

It should be mentioned that the present invention could further adopt the capillary structural design. For example, please refer to FIG. 2, which is a partial enlarged cross-sectional diagram of the liquid-returning tube 16 in FIG. 1 being immersed in the cooling solution 24. As shown in FIG. 2, in this embodiment, the immersion cooling apparatus 10 could further include a capillary structure 36. The capillary structure 36 is disposed in the liquid-returning tube 16. Accordingly, when the heat-dissipating tube 18 cools the steam from the steam-discharging tube 14 into the liquid quickly via the heat-dissipating device 34 contacting the external environment, the liquid flows through the liquid-returning tube 16 and then flows into the cooling solution 24 through the third tube end 30 immersed in the cooling solution 24 more quickly via guidance of the capillary structure 36, so as to prevent the backflow of the liquid and reduce the flow resistance in the heat-dissipating tube 18 for further improving the liquid-returning efficiency of the liquid-returning tube 16 and the heat-dissipating performance of the immersion cooling apparatus 10.

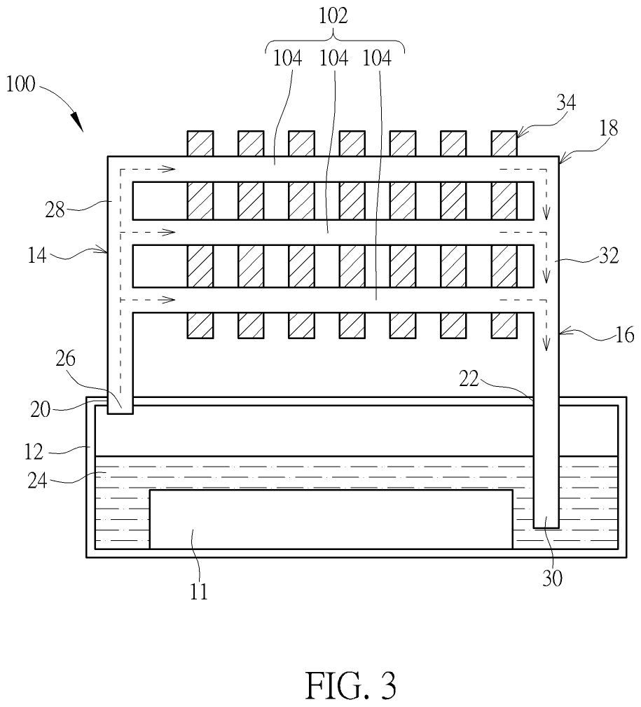

Moreover, the heat-dissipating tube design adopted by the present invention is not limited to the aforesaid embodiment. For example, please refer to FIG. 3, which is a cross-sectional diagram of an immersion cooling apparatus 100 according to another embodiment of the present invention. Components both mentioned in this embodiment and the aforesaid embodiment represent components with similar structures or functions, and the related description is omitted herein. As shown in FIG. 3, the immersion cooling apparatus 100 includes the chamber 12, the steam-discharging tube 14, the liquid-returning tube 16, the heat-dissipating device 34, and a heat-dissipating tube 102. In this embodiment, the heat-dissipating tube 102 includes at least one heat-dissipating pipe 104 (three heat-dissipating pipes 104 arranged in parallel in FIG. 3, but not limited thereto, meaning that arrangement and amount of the heat-dissipating pipes 104 of the immersion cooling apparatus 100 could be varied according to the practical application of the immersion cooling apparatus 100). The heat-dissipating pipe 104 is disposed through the heat-dissipating device 34 (e.g. the heat-dissipating fin structure). The heat-dissipating pipe 104 is communicated with the second tube end 28 of the steam-discharging tube 14 and the fourth tube end 32 of the liquid-returning tube 16 and is spaced apart from the chamber 12. As such, the heat-dissipating device 34 can absorb the heat energy of the steam flowing into the heat-dissipating pipe 104 for quickly cooling the steam into the liquid.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An immersion cooling apparatus comprising:
a chamber having a steam-discharging outlet and a liquid-returning inlet for storing a cooling solution and containing a heat-generating member to make the heat-generating member immersed in the cooling solution;
a steam-discharging tube having a first tube end and a second tube end, the first tube end being communicated with the steam-discharging outlet and located above the cooling solution to discharge steam generated by the cooling solution when the cooling solution absorbs heat energy of the heat-generating member to leave the chamber through the first tube end;
a liquid-returning tube having a third tube end and a fourth tube end, the third tube end passing through the liquid-returning inlet to be immersed in the cooling solution; and
a heat-dissipating tube communicated with the second tube end and the fourth tube end and spaced apart from the chamber for cooling the steam from the steam-discharging tube into liquid and returning the liquid to the cooling solution through the liquid-returning tube.

2. The immersion cooling apparatus of claim 1 further comprising:
a heat-dissipating device disposed on the heat-dissipating tube to be spaced apart from the chamber for absorbing the heat energy of the steam flowing into the heat-dissipating tube to cool the steam into the liquid.

3. The immersion cooling apparatus of claim 2, wherein the heat-dissipating device is a heat-dissipating fin structure, and the heat-dissipating tube is disposed through the heat-dissipating fin structure in a manner of bending back and forth, so as to make the heat-dissipating fin structure absorb the heat energy of the steam flowing into the heat-dissipating tube to cool the steam into the liquid.

4. The immersion cooling apparatus of claim 2, wherein the heat-dissipating device is a heat-dissipating fin structure, the heat-dissipating tube comprises at least one heat-dissipating pipe, and the at least one heat-dissipating pipe is disposed through the heat-dissipating fin structure, so as to make the heat-dissipating fin structure absorb the heat energy of the steam flowing into the at least one heat-dissipating pipe to cool the steam into the liquid.

5. The immersion cooling apparatus of claim 1 further comprising:
a capillary structure disposed in the liquid-returning tube for returning the liquid to the cooling solution through the liquid-returning tube.
